(19) United States
(12) Patent Application Publication
(10) Pub. No.: US 2011/0176372 A1
(43) Pub. Date: Jul. 21, 2011

(54) MEMORY INTERFACE

(75) Inventors: Takahide BABA, Hyogo (JP); Isao KAWAMOTO, Hyogo (JP); Daisuke MURAKAMI, Kyoto (JP); Yuji TAKAI, Osaka (JP)

(73) Assignee: PANASONIC CORPORATION, Osaka (JP)

(21) Appl. No.: 13/076,930

(22) Filed: Mar. 31, 2011

Related U.S. Application Data
(63) Continuation of application No. PCT/JP2009/004974, filed on Sep. 29, 2009.

(30) Foreign Application Priority Data
Oct. 1, 2008 (JP) 2008-256661

(51) Int. Cl. G11C 7/10

(52) U.S. Cl. 365/189.05

(57) ABSTRACT

The memory interface includes: a first data latch unit that delays a strobe signal from a memory device, through a first variable delay unit and reads the strobe signal as a first data signal; and a second data latch unit that delays the same strobe signal through the second variable delay unit and reads the strobe signal as a second data signal. The memory interface uses the data read by the first data latch unit in a normal memory access operation, detects a boundary of the delay amount by comparing the data with the data read by the second data latch unit, and reflects the boundary on the delay amount of the first variable delay unit. Thereby, the delay amount can be corrected without suspending the normal memory access operation.

### CROSS REFERENCE TO RELATED APPLICATION

This is a continuation application of PCT application No. PCT/JP2009/004974 filed on Sep. 29, 2009, designating the United States of America.

### BACKGROUND OF THE INVENTION

(1) Field of the Invention

The present invention relates to a memory interface capable of continuously adjusting timing to access a memory device during a normal memory access operation.

(2) Description of the Related Art

In order to cope with an increase in a processing amount, recent memory systems often use memory devices capable of inputting and outputting data in synchronization with clocks, such as a Synchronous Dynamic Random Access Memory (SDRAM). These memory devices input and output data (DQ) in synchronization with rising and falling edges of data strobe signals (DQS).

In particular, data valid periods for the strobe signals tend to be shorter along with increase in the operating frequency. Considering variations in timing relationship between data and a strobe signal due to the process properties and changes in temperature and voltage, stable input and output of data is becoming difficult.

Under such circumstances, a technique is used in which a calibration operation is performed while suspending a normal memory access operation. Here, the calibration operation is to adjust access timing between data and a strobe signal (Japanese Unexamined Patent Application Publication No. 2004-074623 hereinafter referred to as Patent Reference 1).

Using such a technique, the timing variation corresponding to the variation in the process properties of each chip can be eliminated from the subject timing variations.

The access timing between data and strobe signals can be generally adjusted by including a variable delay unit including a variable delay element corresponding to the data or the strobe signals. The variable delay unit instructs a delay amount.

With the accelerated increase in the operating frequency and the dominant use of Double Data Rate (DDR)-SDRAM in recent years, a period for defining data is becoming shorter, and the need to adjust the access timing with higher precision is growing. The DDR-SDRAM is a memory in which data is changed per half clock cycle.

The access timing needs to be adjusted while suspending the normal memory access operation in the conventional calibration operation. Thus, when the access timing between data and strobe signals varies according to the changes in temperature and voltage, it is necessary to temporarily suspend the normal memory access operation and restart the calibration operation.

Since variations in access timing during the calibration operation cannot be absorbed, the access timing variation needs to fall within an operation margin as the variations in access timing during the normal operation.

Once the operating frequency is accelerated, as the period for defining data is prolonged, a period secured as an operating margin is shortened. Thus, the access timing variation hardly falls within the operation margin. In order to have a larger operation margin, it is necessary to take some measures against the decrease in the operating margin, such as a process jitter and an internal jitter or to frequently perform the calibration operation to reduce the access timing variation.

When the calibration operation is frequently performed, there is a problem that the normal memory access operation cannot be performed and the processing stops during the calibration operation.

The present invention has an object of providing a technique that enables elimination of the access timing variation from the operating margin by adjusting the access timing during the normal memory access operation.

### SUMMARY OF THE INVENTION

In order to achieve the object, the memory interface according to an aspect of the present invention is a memory interface connected to a memory device through signal lines including at least one data signal line and at least one strobe signal line, and includes; a first variable delay unit configured to delay a strobe signal outputted from the memory device by a first delay amount, and output the strobe signal as a first strobe signal; a first data latch unit configured to read a data signal as a first data signal in synchronization with the first strobe signal, the data signal being outputted from the memory device; a first delay control unit configured to set the first delay amount to the first variable delay unit; a second variable delay unit configured to delay the strobe signal by a second delay amount, and output the strobe signal as a second strobe signal; a second data latch unit configured to read the data signal as a second data signal in synchronization with the second strobe signal; a second delay control unit configured to set the second delay amount to the second variable delay unit; a comparator that compares the first data signal with the second data signal; and a delay determining unit configured to record a result of the comparison by the comparator, a first reference delay amount for the first delay control unit, and a second reference delay amount for the second delay control unit, and determine a new first reference delay amount for the first delay control unit and a new reference second delay amount for the second delay control unit, based on the result of the comparison, the first reference delay amount, and the second reference delay amount that are recorded, wherein the first delay control unit is configured to set a new first delay amount to the first variable delay unit, based on the new first reference delay amount, and the second delay control unit is configured to set a new second delay amount to the second variable delay unit, based on the new second reference delay amount.

With the configuration, data latched by the first data latch unit can be output to an applied device that uses the memory device, through the memory interface during a normal memory access operation. At the same time, the second data latch unit can observe the delay amount for access timing, and calibrate the access timing by reflecting a result of the observation to the first data latch unit, without suspending the normal memory access operation.

Furthermore, the memory interface may further include a toggle detector that detects that a value of the first data signal read by the first data latch unit has been toggled, wherein the comparator may perform the comparison when the toggle detector detects that the value of the first data signal has been toggled. Thereby, the access timing of the second data latch unit can be adjusted using data latched by the first data latch unit as an expectation value, and the delay amount can be observed using data used during the normal memory access operation without preparing any expectation value in advance.

Furthermore, when the memory interface is connected to the memory device through data signal lines, the comparator may select one of the data signal lines, and may compare the first data signal and the second data signal that are obtained from the selected data signal line. Thereby, a footprint of a mounting circuit can be reduced.

Furthermore, by mounting a circuit for managing the delay observation operations, the power consumption can be reduced with reduction in the frequency of the delay observation operations. Moreover, a technique in case that the delay observation operations are not performed for a long period can be added.

Furthermore, by mounting a logical operation circuit for data, a toggle rate can be improved, and the frequency of delay observation operations can be prevented from being extremely reduced.

The access timing between data and strobe signals can be continuously adjusted even during a normal memory access operation.

### FURTHER INFORMATION ABOUT TECHNICAL BACKGROUND TO THIS APPLICATION

The disclosure of Japanese Patent Application No. 2008-256661 filed on Oct. 1, 2008 including specification, drawings and claims is incorporated herein by reference in its entirety.

The disclosure of PCT application No. PCT/JP2009/004974 filed on Sep. 29, 2009, including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a functional block diagram illustrating an example of a configuration of a memory system according to Embodiment 1;

FIG. 2 is a flowchart illustrating an example of operations for adjusting a delay amount according to Embodiment 1;

FIG. 3 is a functional block diagram illustrating a configuration of part of the memory system according to Embodiment 1;

FIG. 4 is a functional block diagram illustrating an example of a configuration of a memory system according to Embodiment 2;

FIG. 5 is a functional block diagram illustrating a configuration of part of the memory system according to Embodiment 2;

FIG. 6 is a flowchart illustrating an example of operations for adjusting a delay amount according to Embodiment 2;

FIG. 7 is a functional block diagram illustrating a configuration of part of the memory system according to Embodiment 3;

FIG. 8 is a functional block diagram illustrating a configuration of part of the memory system according to Embodiment 4; and

FIG. 9 is a functional block diagram illustrating an example of a configuration of a memory system according to Embodiment 5.

### DESCRIPTION OF THE PREFERRED EMBODIMENTS

Embodiments according to the present invention will be described with reference to drawings.

### Embodiment 1

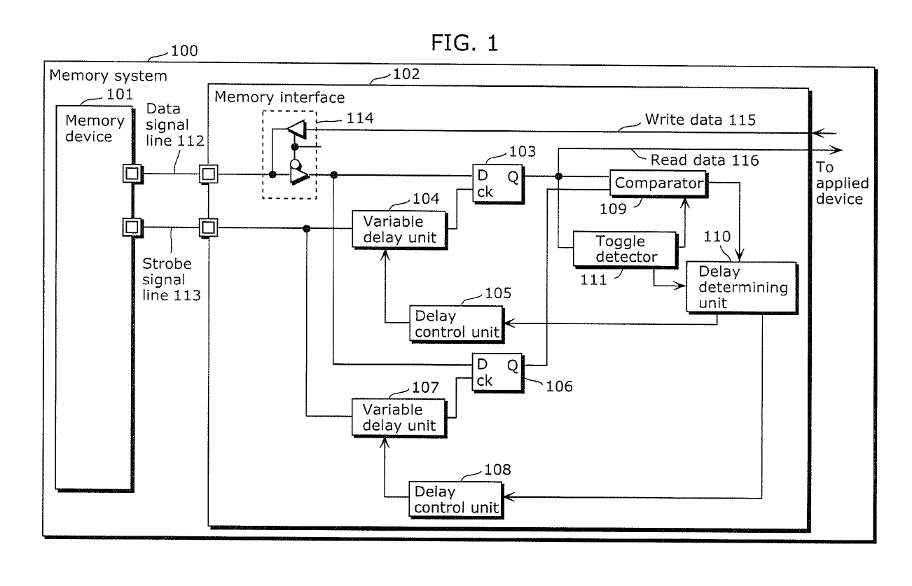

FIG. 1 is a functional block diagram illustrating a configuration of a memory system 100 according to Embodiment 1 in the present invention.

The memory system 100 includes a memory device 101 and a memory interface 102. The memory device 101 and the memory interface 102 are at least connected to a data signal line 112 and a strobe signal line 113.

The memory device 101 may be a Single Data Rate (SDR)-SDRAM that latches data at one of rising and falling edges of strobe signals or a Double Data Rate (DDR)-SDRAM that latches data at both of the rising and falling edges of strobe signals.

The configuration and operations related to one of the rising and falling edges of strobe signals will be hereinafter briefly described to the point.

The data signal line 112 is used for transferring data to be written from the memory interface 102 to the memory device 101 or read from the memory device 101, and is, generally, a bidirectional signal line. In FIG. 1, although the data signal line 112 is composed of a single line, it may be composed of data signal lines corresponding to the strobe signal line 113.

When the memory interface 102 writes data to the memory device 101, the strobe signal line 113 is used for outputting a write strobe signal from the memory interface 102 to the memory device 101. Conversely, when the memory interface 102 reads data from the memory device 101, the strobe signal line 113 is used for outputting a read strobe signal from the memory device 101 to the memory interface 102 and is, generally, a bidirectional signal line.

The memory interface 102 includes a first data latch unit 103, a first variable delay unit 104, a first delay control unit 105, a second data latch unit 106, a second variable delay unit 107, a second delay control unit 108, a comparator 109, a delay determining unit 110, a toggle detector 111, and a direction control unit 114.

When a DDR-SDRAM is used as the memory device 101, two sets of the constituent elements of the memory interface 102 may be provided for the single strobe signal line 113 so as to correspond to the rising and falling edges of strobe signals. Thus, the timings of the rising and falling edges of strobe signals can be separately adjusted.

Since the data signal line 112 is generally a bidirectional signal as described above, the direction control unit 114 controls the data signal line 112 for transferring write data 115 from an applied device and for transferring read data 116 to the first data latch unit 103 and to the second data latch unit 106.

The applied device is a circuit for using the memory device 101 through the memory interface 102, and functions of the applied device are not limited according to the present invention. The applied device may be a Central Processing Unit (CPU), for example.

The first data latch unit 103 latches data transmitted through the direction control unit 114, using a strobe signal that is a delayed signal from the first variable delay unit 104 through the strobe signal line 113. The latched data is not only transmitted to and used by the applied device but also transmitted to the comparator 109.

The second data latch unit 106 latches data transmitted through the direction control unit 114, using a strobe signal that is a delayed signal from the second variable delay unit 107 through the strobe signal line 113. The latched data is transmitted to the comparator 109 and further to the toggle detector 111.

The first variable delay unit 104 adjusts timing between (i) the strobe signal transmitted through the strobe signal line 113 and (ii) a data signal transmitted to the first data latch unit 103 through the data signal line 112 and the direction control unit 114. The first variable delay unit 104 includes a delay line that can change a delay amount. Thereby, the timing can be adjusted.

The second variable delay unit 107 adjusts timing between (i) the strobe signal transmitted through the strobe signal line 113 and (ii) a data signal transmitted to the second data latch unit 106 through the data signal line 112 and the direction control unit 114. The second variable delay unit 107 includes a delay line that can change a delay amount. Thereby, the timing can be adjusted.

The first delay control unit 105 calculates a first delay amount that is an amount adjusted by the delay line included in the first variable delay unit 104, using a first reference delay amount indicated by the delay determining unit 110, and sets the calculated first delay amount to the first variable delay unit 104.

The second delay control unit 108 calculates a second delay amount that is an amount adjusted by the delay line included in the second variable delay unit 107, using a second reference delay amount indicated by the delay determining unit 110, and sets the calculated second delay amount to the second variable delay unit 107.

The comparator 109 compares a value of the data latched by the first data latch unit 103 with a value of the data latched by the second data latch unit 106, and transmits a result indicating whether or not the values match each other to the delay determining unit 110.

The delay determining unit 110 records the result obtained from the comparator 109, the first reference delay amount for the first delay control unit 105, and the second reference delay amount for the second delay control unit 108. The delay determining unit 110 determines new first and second reference delay amounts appropriate for the first delay control unit 105 and the second delay control unit 108, with reference to the records, and updates the records with the determined new first and second reference delay amounts.

When data signal lines 112 are provided and bit data items are transmitted from the data signal lines 112 in parallel, a pair of the first data latch unit 103 and the first variable delay unit 104 is provided for each of the data signal lines 112 to output a corresponding one of the bit data items to an applied device. In contrast, multiple pairs of the second data latch unit 106 and the comparator 109 may be provided for all of the data signal lines 112, or provided for only part of the data signal lines 112.

When the pair of the second data latch unit 106 and the comparator 109 is provided for each of the data signal lines 112, the delay timing can be separately adjusted for each of the data signal lines 112. Furthermore, when the pairs of the second data latch unit 106 and the comparator 109 are provided for only the part of the data signal lines 112, the adjustment amount calculated for the part of the data signal lines 112 can be determined as a preset delay amount of all of the data signal lines 112. Embodiment 2 will describe an example of a case where the data signal lines 112 are provided in detail.

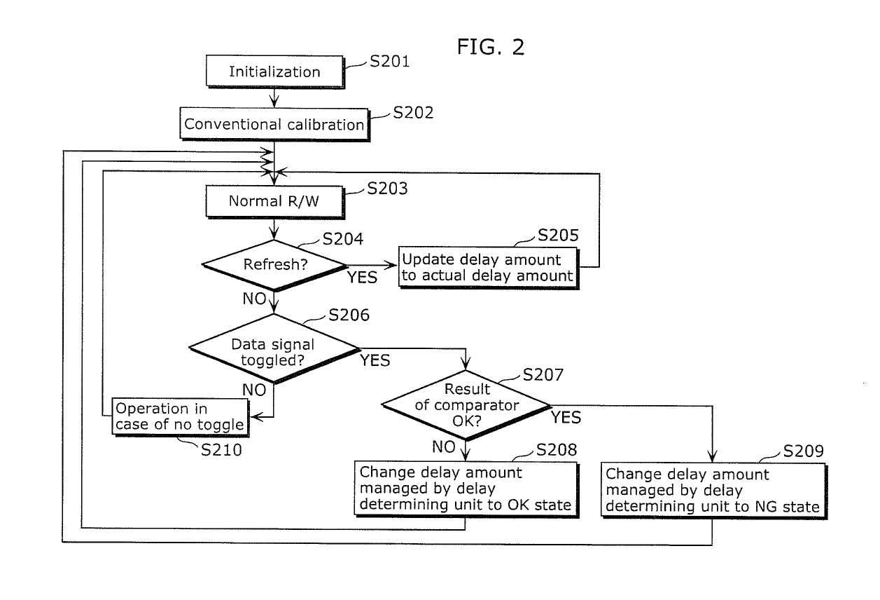

FIG. 2 is a flowchart for explaining operations of adjusting access timing between data that has been continued during a normal operation and a strobe signal in the memory system 100 according to Embodiment 1 in the present invention.

At Step S201, an overall system including the memory system 100 is started and initialized. An example of the operation at Step S201 is an operation after releasing a general power-on reset operation.

At Step S202, the delay amount of the first variable delay unit 104 is adjusted to the delay amount such that the first data latch unit 103 can latch a data signal using a strobe signal. As one example, the technique disclosed in Patent Reference 1 can be used in the operation at Step S202.

At Step S203, the normal memory access operation is performed.

At Step S204, it is determined whether or not the operation is a refresh operation. When a DRAM is used as the memory device 101, generally, it is necessary to suspend the normal operation and perform the refresh operation. The operation at Step S205 is performed in synchronization with the refresh operation. Otherwise, determination at Step S206 is performed.

At Step S206, the toggle detector 111 detects whether or not a value of the data latched by the first data latch unit 103 has been toggled. When the data has been toggled, the determination at Step S207 is performed. Otherwise, the operation at Step S210 in the case of no toggle is performed, and the normal memory access operation is performed at Step S203.

At Step S207, the comparator 109 compares a value of the data signal latched by the first data latch unit 103 with a value of the data signal latched by the second data latch unit 106. When the values match each other in the comparison, the operation at Step S209 is performed. Otherwise, the operation at Step S208 is performed. Since the determination at Step S207 is performed only when the toggle detector 111 detects that the data has been toggled, it is clear that matching values indicate that the second data latch unit 106 can correctly latch the data, and that non-matching values indicate that the second data latch unit 106 cannot correctly latch the data. The delay determining unit 110 records the result. The delay determining unit 110 calculates a range of delay amounts using the record, such that the second data latch unit 106 can correctly latch data.

At Step S208, the delay amount of the second variable delay unit 107 managed by the delay determining unit 110 is changed so as to narrow a difference between the delay amount of the second variable delay unit 107 and the delay amount implemented by the first variable delay 104 (that is, in a direction of eliminating an NG state).

Since Step S208 is performed when a result obtained by the first data latch unit 103 and a result obtained by the second data latch unit 106 do not match each other, a series of Steps S204 to S208 is repeated, until (i) the delay amount of the second variable delay unit 107 approximates the delay amount of the first variable delay unit 104 and (ii) the delay amount of the second variable delay unit 107 is changed from a delay amount such that the second data latch unit 106 cannot correctly latch data to a delay amount such that the second data latch unit 106 can correctly latch data.

Step S209 is an operation step for changing the delay amount of the second variable delay unit 107 managed by the delay determining unit 110 so as to widen a difference between the delay amount of the second variable delay unit 107 and the delay amount implemented by the first variable delay unit 104 (that is, in a direction of a boundary of an OK state).

Since Step S209 is performed when a result obtained by the first data latch unit 103 and a result obtained by the second data latch unit 106 match each other, a series of Steps S204 to S209 is repeated, until (i) the difference between the delay amount of the second variable delay unit 107 and the delay amount of the first variable delay unit 104 widens and (ii) the delay amount of the second variable delay unit 107 is changed from a delay amount such that the second data latch unit 106 can correctly latch data to a delay amount such that the second data latch unit 106 cannot correctly latch data.

When the delay amount of the second variable delay unit 107 is reduced at Step S209, a minimum boundary amount is calculated such that data cannot be correctly latched when the delay amount is smaller than the minimum boundary amount. When the delay amount of the second variable delay unit 107 is increased at Step S209, a maximum boundary amount is calculated such that data cannot be correctly latched when the delay amount is larger than the maximum boundary amount.

As described above, with the series of Steps S204 to S208 or the series of Steps S204 to S209, the delay amount of the second variable delay unit 107 is set approximately closer to a resolution of the delay amount of the second variable delay unit 107, compared to the delay amount of the second data latch unit 106 that is at a boundary between the delay amount with which the second data latch unit 106 can correctly latch data and the delay amount with which the second data latch unit 106 cannot correctly latch data.

With the series of delay observation operations from Steps S206 to S208 or from Steps S206 to S209, the delay amount of the second variable delay unit 107 with which the second data latch unit 106 can correctly latch data is recorded in the delay determining unit 110.

At Step S205, the delay amount desirably delayed by the first variable delay unit 104 is calculated using the delay amount recorded in the delay determining unit 110, and the calculated delay amount is set to the first delay control unit 105 at Step S205. The delay amount set to the first delay control unit 105 is, for example, a value obtained by factoring in a safety margin in the delay amount recorded in the delay determining unit 110.

Since Step S205 is performed during refresh, the first delay control unit 105 can change the delay amount of the first variable delay unit 104 without suspending access to the memory device 101 during the normal operation.

Step S210 is an operation when a value of the data signal line 112 is not toggled.

Since the operation of correcting the delay amount at Steps S208 and 209 is performed only when a value of the data signal line 112 has been toggled, it is possible to prevent the delay amount from substantially deviating from a target amount by compensating an operation in which the delay amount is not corrected for a long period at S210.

As a specific example, at Step S210, correcting the delay amount using software through output of an interrupt signal (not illustrated) to a CPU that is an example of an applied device can prevent a delay amount from substantially deviating from a target amount.

Furthermore, jumping to Step S202, the delay amount can be prevented from substantially deviating from a target amount by performing another method of suspending the normal memory access operation and correcting the delay amount in the same manner after the initialization.

In the aforementioned description, although the delay amount to be set to the first delay control unit 105 is determined by calculating one of (i) a minimum boundary amount with which data can or cannot be correctly latched and (ii) a maximum boundary amount with which data can or cannot be correctly latched and factoring in a safety margin in the calculated boundary amount, the delay amount may be set using both the minimum boundary amount and the maximum boundary amount.

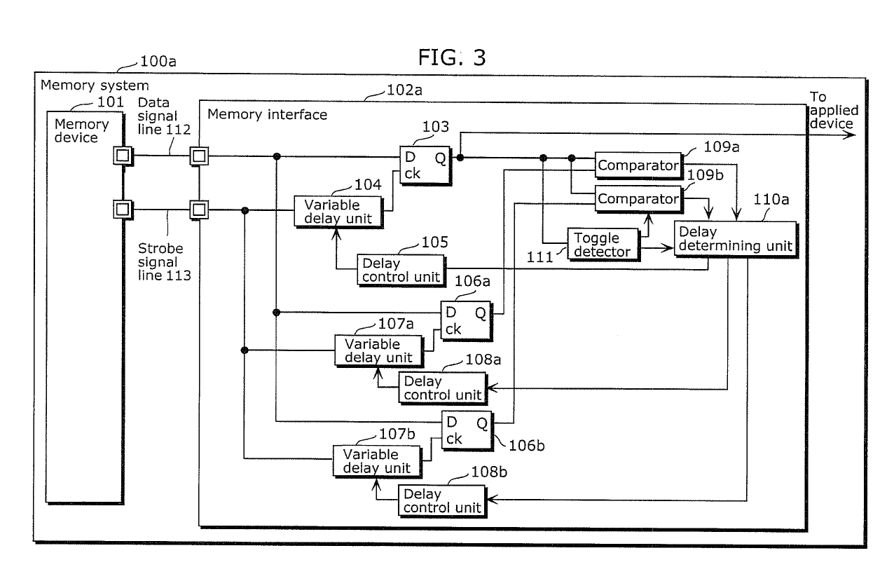

FIG. 3 is a functional block diagram illustrating an example of a configuration of a memory system 100a including a memory interface 102a according to a modification of Embodiment 1.

The memory interface 102a differs from the memory interface 102 in that both the minimum boundary amount and the maximum boundary amount are calculated for setting the delay amount to the first delay control unit 105.

The memory interface 102a includes a second variable delay unit 107a, a second data latch unit 106a, a second delay control unit 108a, and a comparator 109a to calculate the minimum boundary amount, and includes a second variable delay unit 107b, a second data latch unit 106b, a second delay control unit 108b, and a comparator 109b to calculate the maximum boundary amount. The delay determining unit 110a determines an intermediate amount between the minimum boundary amount and the maximum boundary amount that are calculated, as a delay amount to be set to the first delay control unit 105.

With the configuration, the delay amount of the first delay control unit 105 can be appropriately set, for example, without depending on the precision of a safety margin.

### Embodiment 2

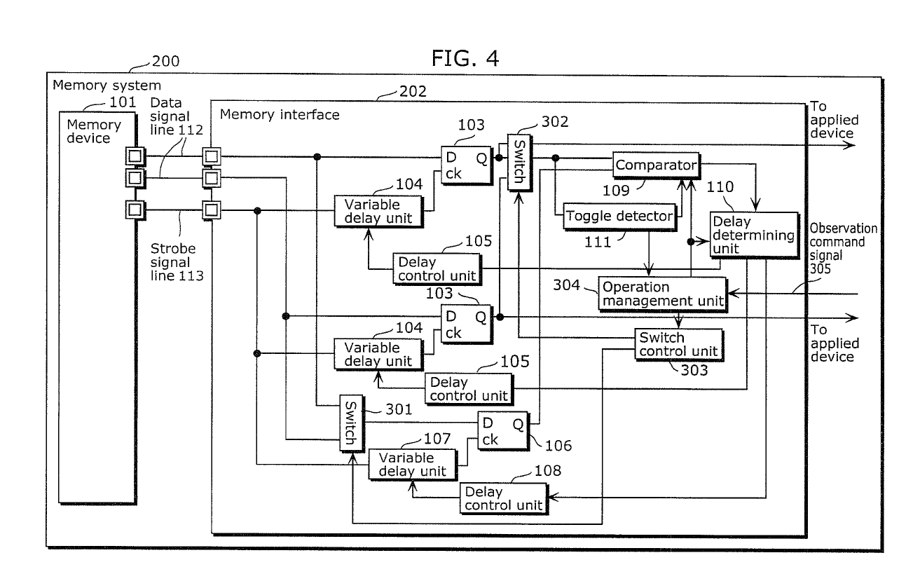

FIG. 4 is a functional block diagram illustrating a configuration of a memory system 200 according to Embodiment 2 in the present invention.

The memory system 200 in FIG. 4 includes a memory interface 202 obtained by adding switches 301 and 302, a switch control unit 303, and an operation management unit 304 to the memory interface 102 of the memory system 100 (FIG. 1) according to Embodiment 1. Furthermore, the memory system 200 includes data signal lines 112, and each of the first data latch unit 103 and the first variable delay unit 104 corresponds to one of the data signal lines 112. Other constituent elements are the same as those in FIG. 1, and a direction control unit 114 and write data 115 have the same configurations as those of FIG. 1 although they are omitted in FIG. 4.

Generally, a memory control circuit that controls a DRAM includes a control circuit for generating a refresh command. In addition to the configuration in FIG. 4, the memory system 200 has a configuration for starting a delay observation operation for each predetermined number of refresh operations.

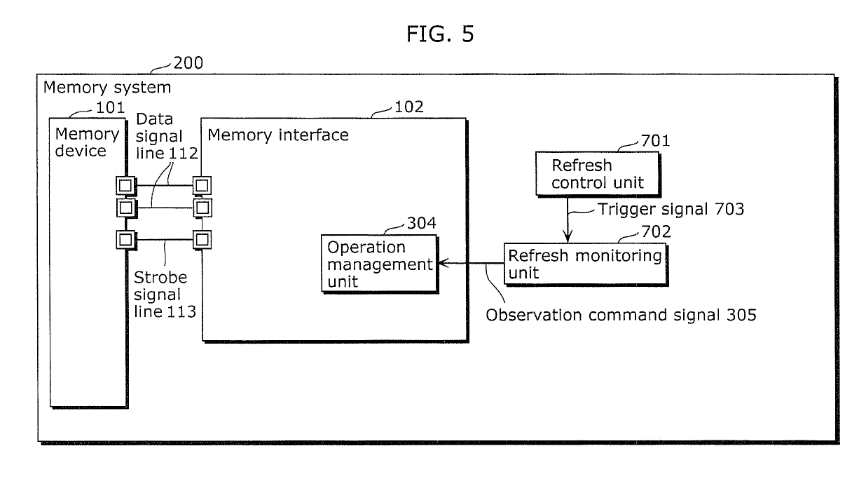

FIG. 5 is a functional block diagram illustrating an example of the memory control circuit. In FIG. 5, a refresh monitoring unit 702 counts the number of refresh operations, in response to a trigger signal 703 indicating a refresh command from a refresh control unit 701.

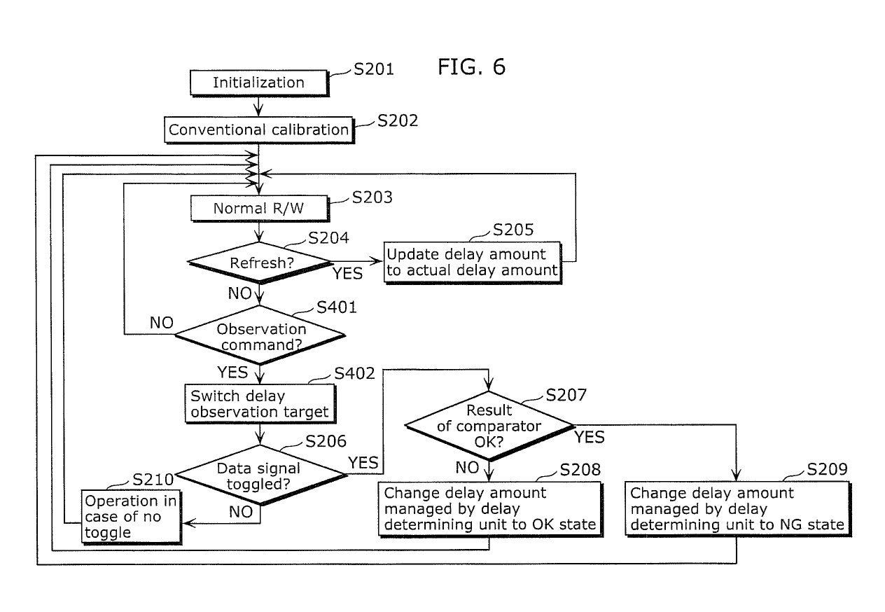

The operations of adjusting access timing between data that has been continued during a normal operation and a strobe signal in the memory system 200 according to Embodiment 2 in the present invention will be described with reference to a flowchart in FIG. 6. The flowchart in FIG. 6 is obtained by adding Steps S401 and S402 to the flowchart in FIG. 2.

The refresh monitoring unit 702 outputs an observation command signal 305 to the operation management unit 304, when the number of refreshes reaches a constant value.

At Step S401, the operation management unit 304 starts a series of delay observation operations upon receipt of the observation command signal 305.

At Step S402, the switch control unit 303 switches data to another targeted for the series of delay observation operations.

Then, a delay amount of the target data is observed by performing the operations from Steps S206 to S209. The observed delay amount is used for changing the delay amount of the first variable delay unit 104 through the first delay control unit 105 in which the data whose delay amount has been observed is processed.

Furthermore, with use of another delay amount observed from different data, the delay amount can be prevented from substantially deviating from a target amount beyond a difference between the data and the different data.

According to the configuration in FIG. 4, the second delay control unit 108, the second variable delay unit 107, and the second data latch unit 106 are shared for each observation target, by switching, between the switches 301 and 302, respective data signals from the data signal lines 112 that are targeted for the observation of delay amounts. Thus, a footprint of an integrated circuit device can be reduced.

The configuration for switching between observation targets of delay amounts using the switches 301 and 302 is effective in the following cases.

For example, Embodiment 1 describes the configuration in which the second delay control unit 108, the second variable delay unit 107, and the second data latch unit 106 are separately provided for rising and falling edges of a strobe signal when a DDR-SDRAM is used as the memory device 101. In this case, the data signal corresponding to each of the rising and falling edges of a strobe signal is targeted for observation of a delay amount.

As an application of the configuration of switching between data signals from the data signal lines 112 using the switches 301 and 302, a switch for extracting a data signal for a period that corresponds to each of the rising and falling edges of a strobe signal is provided, and the data signals extracted by the switch for the respective periods are shared by the second delay control unit 108, the second variable delay unit 107, and the second data latch unit 106. Then, the data signals are processed with time division, and thus, a footprint of an integrated circuit device can be reduced.

Furthermore, for example, as described in the modification of Embodiment 1, even when both a maximum boundary amount and a minimum boundary amount are targeted for the observation, the second delay control unit 108, the second variable delay unit 107, and the second data latch unit 106 are shared for these observation targets using the switch that switches between the observation targets of the delay amounts. Thus, a footprint of an integrated circuit device may be reduced.

### Embodiment 3

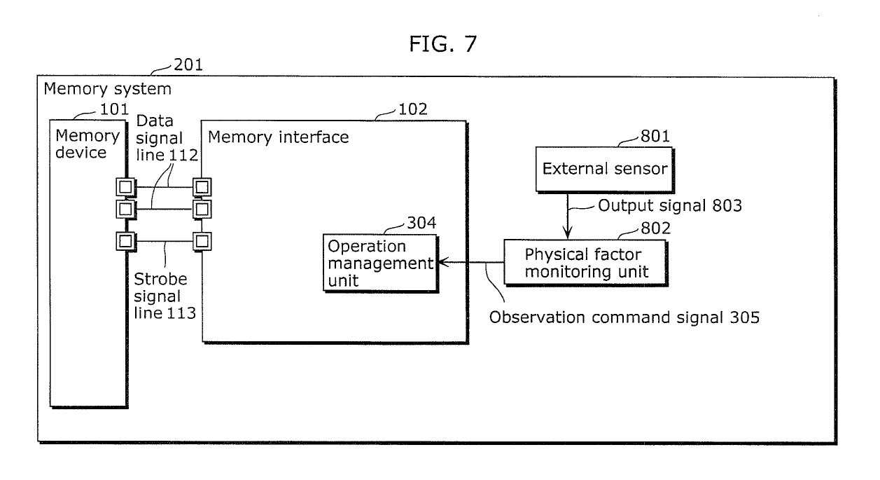

FIG. 7 is a functional block diagram illustrating a configuration of a memory system 201 according to Embodiment 3 in the present invention. The configuration of the memory system 201 is the same as that of the memory system 200 in Embodiment 2 except for the configuration for outputting the observation command signal 305 to the operation management unit 304.

An external sensor 801 in FIG. 7 is a physical sensor for observing a physical factor (disturbance) that influences delay, such as variations in a power-supply voltage. As long as a physical sensor can observe the physical factor that influences delay, such as the variations in a temperature, in addition to the variations in a power-supply voltage, the same advantages can be obtained from the physical sensor.

A physical factor monitoring unit 802 is a circuit that determines that a preset physical factor is satisfied, using an output signal 803 of the physical sensor, and that outputs the observation command signal 305 to the operation management unit 304.

The operations of the memory system 201 are almost the same as those of the memory system 200 that are indicated in the flowchart of FIG. 6.

The memory system 201 observes delay only when a physical factor that variations in the delay exceeds an acceptable range is satisfied, upon receipt of the observation command signal 305 from the physical factor monitoring unit 802 in FIG. 7 as a condition for transitioning from Step S401 to Step S402 for starting the series of delay observation operations.

### Embodiment 4

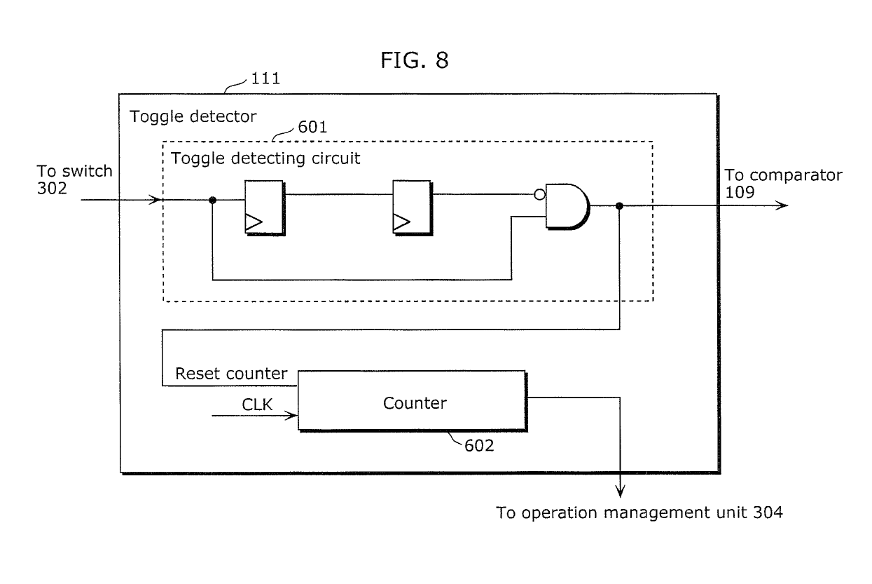

FIG. 8 is a functional block diagram illustrating a specific example of a toggle detector 111 according to Embodiment 4 in the present invention. FIG. 8 is a detailed internal view of the toggle detector 111 in FIG. 4.

A toggle detecting circuit 601 in FIG. 8 shows an example of a circuit configuration for detecting a toggle of a data signal transmitted from the switch 302. There are different circuit configurations of the toggle detecting circuit 601. As long as the toggle of the data signal can be detected, other circuit configurations may be used.

A counter 602 counts a clock signal CLK, measures a period for which a toggle cannot be detected after the counter 602 is reset, using a detection signal transmitted from the toggle detecting circuit 601, and transmits the observation command signal 305 to the operation management unit 304 on condition that the toggle is not detected for a certain period.

The operations of adjusting access timing between data that has been continued during a normal operation and a strobe signal in the memory system 100 according to Embodiment 4 in the present invention will be described with reference to the flowchart in FIG. 6.

The steps in FIG. 6 according to Embodiment 4 are the same as those according to Embodiment 2. When a toggle is not detected, the series of delay observation operations after Step S207 in FIG. 6 are not performed. In this case, since a delay amount is not determined depending on a data value, the actual delay amount may deviate from the set value. Thus, the process moves to Step S202 in accordance with a signal from the counter 602. At Step S202, a delay amount can be appropriately adjusted by suspending the normal memory access operation and correcting the delay amount similarly after the initialization.

Other than moving to Step S202, the operation at Step S205 in FIG. 6 can be performed with reference to the delay amount obtained by observing another data which is stored in the delay determining unit 110 and in which a toggle has been detected.

### Embodiment 5

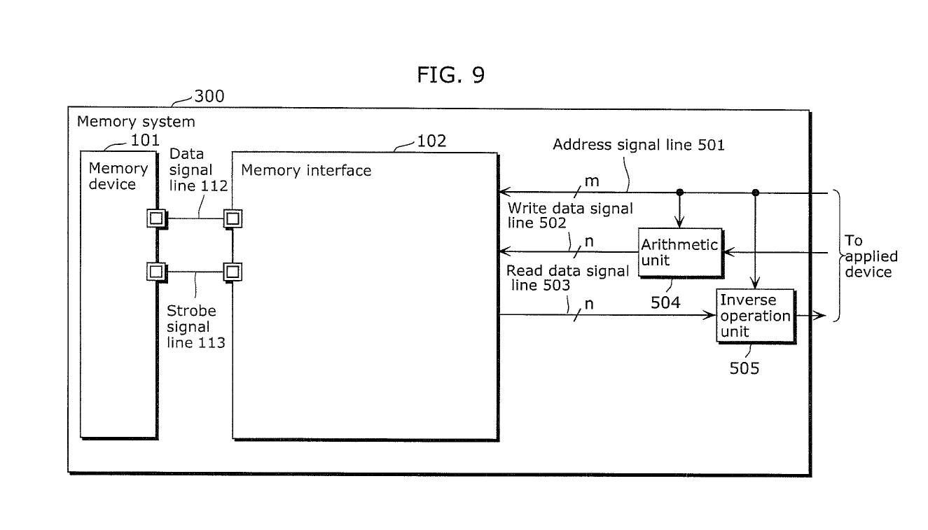

FIG. 9 is a functional block diagram illustrating an example of a configuration of a memory system 300 according to Embodiment 5 in the present invention. FIG. 9 illustrates a read data signal line 503 for transmitting read data 116, a write data signal line 502 for transmitting write data 115, and an address signal line 501 all of which are connected to the memory interface 102 in FIG. 1.

The memory system 300 further includes an arithmetic unit 504 and an inverse operation unit 505 in addition to the memory system 100 in FIG. 1. The arithmetic unit 504 generates the write data 115 by performing a logical operation on (i) an address value transmitted from the address signal line 501 composed of bits and (ii) data given from an applied device, and outputs the write data 115 to the write data signal line 502. The inverse operation unit 505 is a circuit that performs an operation inverse to the logical operation performed by the arithmetic unit 504.

The aforementioned configuration is applicable to the memory system 100 according to Embodiment 1 and the memory system 200 according to Embodiment 2 in the present invention.

With the configuration, even in the case where a toggle hardly occurs from a data signal as in the case where a plurality of pixel data indicating the same color as image data is consecutively stored, the arithmetic unit 504 performs the logical operation on an address value. Thus, the probability of toggling between data to be actually stored in the memory device 101 through the memory interface 102 and data before and after the data will be increased. At the same time, the written data can be accurately read with inclusion of the inverse operation unit 505 at a reading side. Since the arithmetic unit 504 performs the logical operation on an address value, the toggling is not always secured. However, the probability of toggling between consecutive data signals having the same value as image data can be increased.

Although the logical operation is performed on an address signal instead of a data signal in the description, the signal to be processed does not have to be the address signal.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

As described above, even when physical factors that influence a signal delay amount, such as a voltage and a temperature, vary during operations, the delay amount can be corrected with the method of adjusting access timing between the memory system and the memory device according to the present invention, without suspending the normal memory access operation. Thus, the method is useful for a memory system whose operating frequency is being accelerated.

What is claimed is:

1. A memory interface connected to a memory device through signal lines including at least one data signal line and at least one strobe signal line, said memory interface comprising;
a first variable delay unit configured to delay a strobe signal outputted from the memory device by a first delay amount, and output the strobe signal as a first strobe signal;
a first data latch unit configured to read a data signal as a first data signal in synchronization with the first strobe signal, the data signal being outputted from the memory device;
a first delay control unit configured to set the first delay amount to said first variable delay unit;
a second variable delay unit configured to delay the strobe signal by a second delay amount, and output the strobe signal as a second strobe signal;
a second data latch unit configured to read the data signal as a second data signal in synchronization with the second strobe signal;
a second delay control unit configured to set the second delay amount to said second variable delay unit;
a comparator that compares the first data signal with the second data signal; and
a delay determining unit configured to record a result of the comparison by said comparator, a first reference delay amount for said first delay control unit, and a second reference delay amount for said second delay control unit, and determine a new first reference delay amount for said first delay control unit and a new reference second delay amount for said second delay control unit, based on the result of the comparison, the first reference delay amount, and the second reference delay amount that are recorded,
wherein said first delay control unit is configured to set a new first delay amount to said first variable delay unit, based on the new first reference delay amount, and
said second delay control unit is configured to set a new second delay amount to said second variable delay unit, based on the new second reference delay amount.

2. The memory interface according to claim 1, further comprising
a toggle detector that detects that a value of the first data signal read by said first data latch unit has been toggled,
wherein said comparator performs the comparison when said toggle detector detects that the value of the first data signal has been toggled.

3. The memory interface according to claim 1,
wherein said memory interface is connected to the memory device through data signal lines including the at least one data signal line.

4. The memory interface according to claim 3,
wherein said comparator selects one of the data signal lines, and compares the first data signal and the second data signal that are obtained from the selected data signal line.

5. The memory interface according to claim 1,
wherein said memory interface reads the data signal at rising and falling edges of the strobe signal.

6. The memory interface according to claim 1, further comprising
a plurality of second variable delay units configured to process the strobe signal, said plurality of said second variable delay units including said second variable delay unit.

7. The memory interface according to claim 1, further comprising:
an external sensor that observes a physical factor of the memory device; and
an operation management unit configured to cause said second delay control unit to perform a delay observation operation, when said external sensor observes a predetermined physical factor.

8. The memory interface according to claim 1, further comprising
a refresh monitoring unit configured to count the number of refresh operations performed by the memory device; and
an operation management unit configured to cause said second delay control unit to perform a delay observation operation, when the number of refresh operations counted by said refresh monitoring unit is equal to or larger than a predetermined number.

9. The memory interface according to claim 2,
wherein said toggle detector includes a counter that measures an elapsed time since said toggle detector has detected a previous toggle, and
said memory interface suspends a normal memory access operation and corrects a delay amount, when said toggle detector does not detect a toggle for a predetermined period.

10. The memory interface according to claim 2,
wherein said toggle detector includes a counter that measures an elapsed time since said toggle detector has detected a previous toggle, and
said memory interface outputs an interrupt signal to an applied device that uses the memory device through said memory interface, when said toggle detector does not detect a toggle for a predetermined period.

11. The memory interface according to claim 3,
wherein said toggle detector includes a counter that measures an elapsed time since said toggle detector has detected a previous toggle, and
in the case where said toggle detector does not detect a toggle from a data signal that is transmitted through one of the data signal lines for a predetermined period, said memory interface controls delay with reference to a delay amount recorded in said delay determining unit when said toggle detector has detected an other toggle from a data signal that is transmitted through an other one of the data signal lines.

12. The memory interface according to claim 2, further comprising:
an arithmetic unit configured to generate data to be written to the memory device by performing a predetermined logical operation on a data signal and an address signal that are provided from an applied device that uses the memory device through said memory interface; and
an inverse operation unit configured to generate data to be output to the applied device by performing an operation inverse to the logical operation performed by said arithmetic unit, on (i) the address signal provided from the applied device and (ii) data corresponding to the address signal and read from the memory device.
